(19) United States
(12) Patent Application Publication
(10) Pub. No.: US 2012/0206865 A1
(43) Pub. Date: Aug. 16, 2012

(54) Video Mantel for Stimulated Exercise

(76) Inventor: Danny Ray Morris, (US)

(21) Appl. No.: 13/026,861

(22) Filed: Feb. 14, 2011

(51) Int. Cl. H05K 5/00

(52) U.S. Cl. 361/679.01

(57) ABSTRACT

An enclosure designed to provide safe stimulating video entertainment while exercising. This provides motivation to use the exercise equipment on a routine daily basis. The enclosure is mounted to the wall in front of the exercise equipment. It incorporates the styling of a mantel and supports a flat panel display. Within the enclosure are suitable electronic modules to provide content for the display. Power for the electronic modules and display are combined to a single power cable. All cables providing remote connections are routed from the mantel behind a cover to the floor area. This gives a visually clean and appealing appearance for the mantel and surrounding area.

### BACKGROUND

1. Field of Invention

This invention relates to the use of exercise equipment, specifically providing a video display system to stimulate the use of the exercise equipment.

2. Description of Prior Art

Exercise is an essential part of good health and weight control. Exercise equipment such as treadmills, elliptical's, ski simulators, stationary bicycles etc. have been sold and used for many years. Unless the exercise equipment's location provides mental stimulus (visual and audio) we quickly grow disgruntled and bored of the exercise routine and stop using the equipment. A display (TV or monitor with programming) is an ideal solution. This display has unique requirements that must be satisfied to be effective.

In most homes exercise equipment is located in a spare room or corner of the garage. Space is at a premium and the equipment is large so it usually gets pushed to a wall or near a corner. The display requires a small screen at eye level. Because of the close proximity to the display a large screen can cause loss of balance from head movement while watching the action on the screen. Looking straight ahead is best for both balance and reduced strain on the neck and shoulders.

All electronic equipment supporting the display should be located in one easy to reach location. Unobstructed access to the remote controls and electronic modules providing the video programming is necessary for efficient startup and operation while on the exercise equipment. Some exercise equipment generates a lot of noise. Head sets often are the best solution for this. Easy storage and access to them must be provided as well.

All electronic modules and display need to be mounted on the wall. The exercise equipment generates a lot of vibration and transfers this to the floor while in operation. Mounting the display and electronic modules to the wall provides the best isolation from vibration.

Power distribution is a problem. Multiple electronic modules plus the display and the exercise equipment all require separate power cords. The quantity of cords usually exceeds the local wall outlet capacity and creates a wire jungle.

Finally, the solution must be simple to install, low cost and esthetically pleasing. Unless these problems are properly addressed, the equipment will continue to fail to provide the stimulus needed. Several types of partial remedies do exist, gyms in hotels provide one or more TV's for stimulus. Some of the most expensive exercise equipment have TV's built in or provisions for radios such as MP3 players to be plugged in. But no one provides a solution for the masses that is easy to install (retrofit) takes up no extra room and is a complete audio and video solution to users of their exercise equipment.

### EXAMPLES OF PRIOR ART

The Fireplace Shelf and Mantel Support, U.S. Pat. No. 5,711,115, Jan. 27, 1998 incorporates shelves for books, knickknacks etc. The shelving is specific to a fireplace surround and does not provide for hiding the electrical power connection when required. Since a fireplace is required, this is not a reasonable solution with exercise equipment.

Physical Exercise Video System, U.S. Pat. No. 5,888,172, Mar. 30, 1999. Incorporates audio and video to an exercise system to control and provide feedback on the user's performance while using the equipment. No effort was made to entertain the user with this design and no attempt to optimize the layout of the design was made.

Storage Mantel, U.S. Pat. No. 6,056,375, May 2, 2000. This provides storage within the mantel for items such as CD's, cassettes etc. over an existing fireplace (claim 1) but not electronics or wiring for electronics. Not suitable for use with exercise equipment.

The System and Method of Mounting of Audio and Video Components, patent Ser. No. 10/786,576, Aug. 25, 2005. This provides a good solution for mounting one or more modules containing components to a bar that is mounted below a video display. Each module is the container for a subset of components to the total display solution (claim 26). Each module adds to the cost of the complete system. The video display requires an independent mount to the wall further adding to the cost of the installation. The design does not provide a good solution for hiding and aggregating the power cords or routing the cables from the bar (claim 21). Nor does it provide the esthetics of a mantel architectural design.

Surround Entertainment System for a Fireplace, Patent number 108082662, Sep. 22, 2005, adds electronics to fireplace surrounds. This does incorporate electronics in a cabinet mounted to a wall as a fireplace mantel with hidden TV display for secondary use. This requires a fireplace and is not suitable for an exercise equipment solution.

Flat panel display TV stand, patent Ser. No. 11/376,933, Sep. 28, 2006. A wall mounted vertical metal column with adjustable shelves on brackets that hold the electronic modules. The TV display mounts to brackets on the back of the TV that attach to the vertical columns. Wiring between the modules is routed behind the panel to the shelves, TV and floor. The movable shelves provide a flexible solution when electronic modules are replaced that require different shelf height. It also keeps the wall esthetically clean of wiring. One weakness in the design is that newer electronic modules such as video streamers and HDMI switch/splitters use external power supplies, often referred to as a “wall warts”. Their odd size and plug angles make them difficult/impossible to place behind the shallow panels. The only practical solution, which is very unattractive, is placing them on a shelf plugged into a power strip or extension cord. Additionally, this solution is very complex with many components (read expensive). The modern/industrial styling appeals to a limited audience only.

Integrated Entertainment System with Audio Modules, U.S. Pat. No. 325,485, Jul. 5, 2007. Fully integrated console with TV stand. This console is designed for family room listening and/or viewing. It takes up substantial floor space and is not wall mounted. The display for an exercise room needs to be mounted quite high for proper viewing. This console takes up space and is to low for this application.

Exercise Apparatus with Audio-Visual Device, U.S. Pat. No. 297,210, Jul. 17, 2003. This design addresses the problem by attaching an audio video rack with TV to the sporting goods (exercise equipment). Exercise equipment generates tremendous vibration to the floor. These vibrations are transferred to any TV stand on the floor or attached to the exercise equipment. The strain of watching a vibrating TV quickly negates the experience and explains why this has not become popular. This design also takes up additional floor space since it is a rack bolted in front of the exercise equipment.

Comprehensive Multi-purpose Exercise Equipment, patent Ser. No. 11/809,074, Dec. 13, 2007. This design is an improvement to the prior patent by mounting the TV in the front panel reducing the extra floor space required. However, it does not address the vibration problem. Also, mounting the TV in the front console is not the best location. The console is lower than eye level. This jeopardizes ones balance and strains the neck while exercising.

Exercise Machine, patent Ser. No. 11/942,424, May 22, 2008. This is similar to the prior patent. The embodiment is in a control panel for the exercise equipment. This suffers from vibration and visual deficiencies just as the prior patent does.

Raceway System with Separated Wireways for Power and Data Communication, U.S. Pat. No. 6,323,421, Nov. 27, 2001. and Multi-channel Raceway, U.S. Pat. No. 6,972,367, Dec. 6, 2005. This family of patents only addresses the wire jungle problem by enclosing and routing multiple wires.

These and all prior patents listed with these, include a wall mounted raceway and movable cover that encloses the wiring within it. These are good designs for enclosing and hiding multiple signal and power wires on a wall. A simpler solution is sufficient for this application. Enclosing the wires are not required, simply hiding them behind a removable cover is sufficient.

### OBJECTS AND ADVANTAGES

Accordingly, several objects and advantages of my invention are:
(a) Smallest foot print. All of the equipment mounts on the wall in an enclosure above the exercise equipment requiring no extra room in front of the exercise equipment.
(b) The enclosure referred to here as a video mantel mounts to the wall above the front console of the exercise equipment placing the display at the proper eye level height.
(c) All of the electronic modules and display are contained in or on the video mantel within arms reach while on the exercise equipment. This provides full access to all programming controls and headsets.
(d) Vibration isolation is maximized through the wall mounting of the video mantel.
(e) Power distribution is solved by a power strip located within the video mantel to accommodate the various power plugs and wall warts of the electronic modules and display. A single power cord and plug remains to power the entire video mantel.
(f) The jungle of wires interconnecting the electronic modules and display are neatly tied off and hidden from view within a hidden chamber. Further, all remote wiring is hidden behind a wire tunnel.
(g) Installation of the video mantel has been simplified to the mounting of a few wall brackets.
(h) The lines of a fireplace mantle have been incorporated to provide the most esthetically pleasing and broadly accepted architectural feature.
(i) Production costs and therefore cost to the consumer have been minimized by using standard materials and construction methods.
Still further objects and advantages will become apparent from consideration from the ensuing description and drawings.

### DRAWING FIGURES

In the drawings, closely related figures have the same number but different alphabetic suffixes.

FIG. 1 shows a complete video mantel system with all major components.

FIGS. 2a and 2b show front and back views of the video mantel.

FIG. 3 shows the mounting bracket and mating bracket tangs.

FIG. 4 shows the vertical wire tunnel assembly.

Reference Numerals in Drawings

| | | | |
|---|---|---|---|
| 2 Top Shelf | 3 hole | 4 lower shelf | 6 side panel |
| 7 cut out | 8 side panel | 10 side wall | 12 front wall |
| 14 side wall | 16 crown molding | 18 bracket tang | 20 bottom shelf |
| 21 video display | 22 mounting bracket | 23 screw | 24 anchor |
| 25 wood screw | 26 front panel | 28 side panel | 30 tab |
| 32 panel bracket | 33 sheet rock screw | 34 power cord | 35 electronic |
| | | | module |
| 36 power strip | 38 electrical outlet | | |

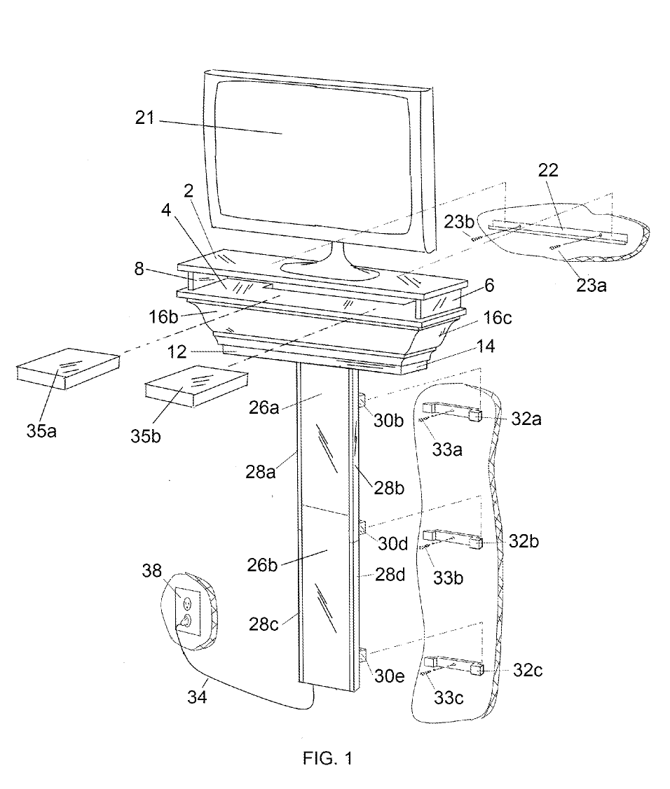

### DESCRIPTION OF FIGS. 1 TO 4

FIGS. 1 through 3 are perspective views of the video mantel assembly. The top shelf 2 is fabricated from suitable material such as plywood to carry the load of a flat panel video display 21. The depth of the top shelf 2 is sized to accommodate the stand of a flat panel video display 21. The width of the top shelf 2 is sized to accommodate the width of the flat panel video display 21 stand and provide additional storage space for any remote controls and headset. The top shelf 2 has a large hole 3 near the back of the shelf. The hole 3 is offset from the center of the shelf to provide clearance for the stand of the video display 21. The hole 3 size is sufficient to accommodate the installation of multiple signal wires and power plug for the video display 21.

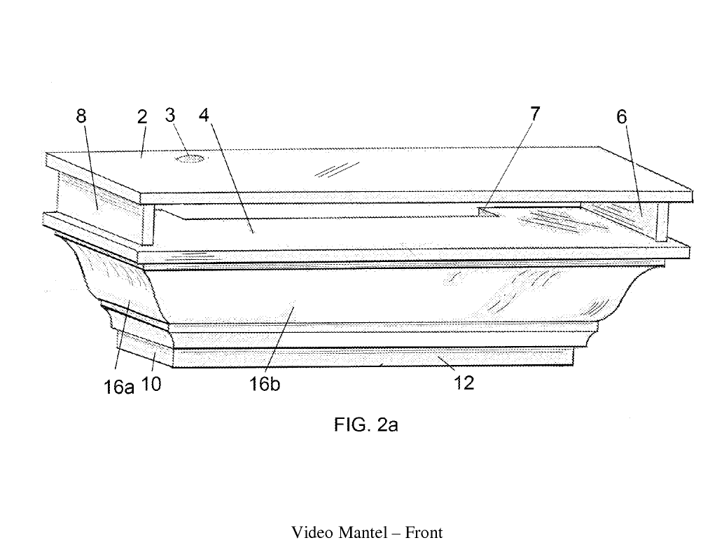

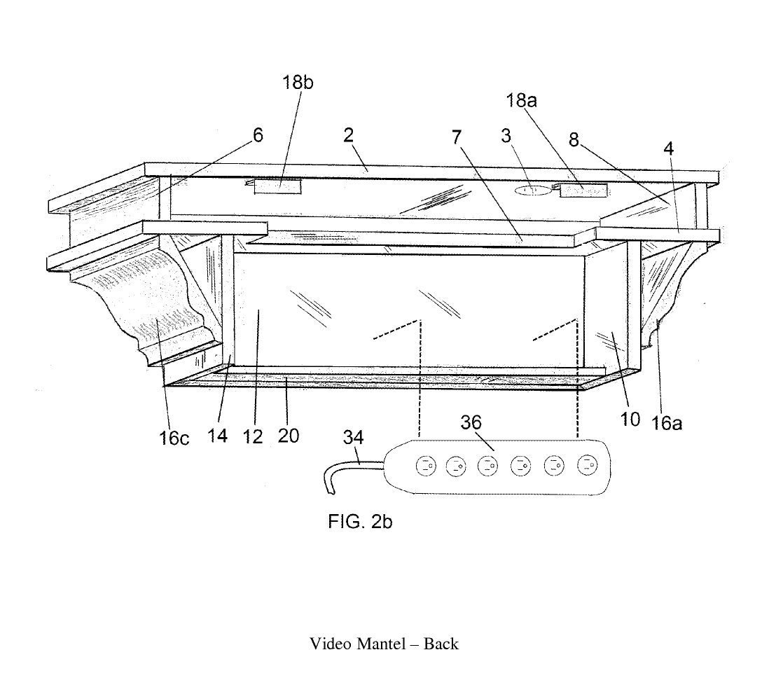

The second shelf 4 made of suitable material such as plywood, is the same overall size as the top shelf 4. The shelves 2 and 4 are separated by vertical side panels 6 and 8 made of suitable material such as wood. The side panels are set back from the side edges of the shelves 2 and 4 by approximately the thickness of the shelves to provide enhanced visual appeal. The height of these side panels 6 and 8 is selected to provide vertical clearance and sufficient cooling space for the electronic modules 35. A lower hidden chamber is formed by side walls 10 and 14, front wall 12, a ceiling from the lower side of shelf 4 and a bottom shelf 20. All fabricated from a suitable material such as wood. The back of the hidden chamber is completed by the wall the video mantel in FIG. 1 is mounted to. The lower shelf 4 has a cut out 7 on the back edge that is positioned over and smaller than the size of the hidden chamber formed by the front wall 12 and side walls 10 and 14. The chamber is further hidden by crown molding on the front 16b and sides 16a and 16c. The outer dimensions of the hidden chamber are determined by the size of the lower shelf 4 minus the horizontal projection of the crown molding 16 and thickness of a shelf. The depth of the hidden chamber is determined by the vertical projection of the crown molding 16 plus about twice the thickness of the shelf 4. The bottom shelf 20 forms the bottom of the hidden chamber. The bottom shelf 20 extends back from the front wall 12 to about half the distance to the wall in FIG. 1 the video mantel FIG. 2 is mounted on. This leaves an opening between the back edge of the bottom shelf 20 to the wall of about half the depth of the hidden chamber. The width of the crown molding 16 is chosen to project the proportions and appearance of a mantel typically seen over a fireplace.

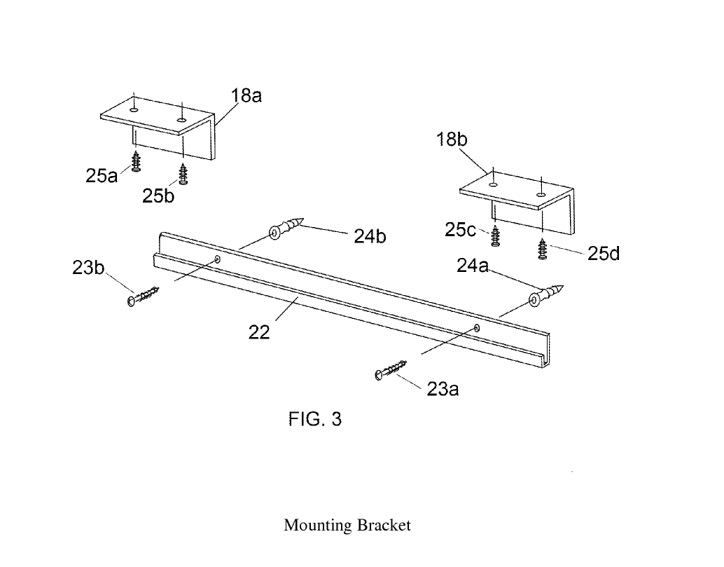

The video mantel FIG. 2 is attached to the wall by way of the bracket tangs 18a and 18b secured to the bottom of the top shelf 2 that slide into the channel of the wall bracket 22. The mounting bracket 22 in FIG. 3 is a metal “J” channel attached to the wall with screws 23a and 23b via anchors 24a and 24b. The spacing between the screws 23 is sufficient to ensure proper lateral and vertical load transfer to the wall. The width of the wall bracket 22 is equal to the spacing between the screws 23 plus the width of the bracket tangs 18a and 18b. The bracket tangs 18a and 18b are metal right angle of sufficient thickness to fit snuggly in the channel of the mounting bracket 22. The bracket tangs 18 are attached to the bottom of the top shelf 2 by wood screws 25. The bracket tangs 18a and 18b are symmetrically spaced about the center line of the top shelf 2 and along the back edge of the top shelf 2. The bracket tangs 18a and 18b are separated by a distance slightly greater than the spacing of screws 23. The bracket tangs 18 will not engage the wall bracket unless the bracket tangs 18 clear the heads of the screws 23. This provides a guide to proper lateral installation of the video mantel FIG. 2 to the wall bracket 22.

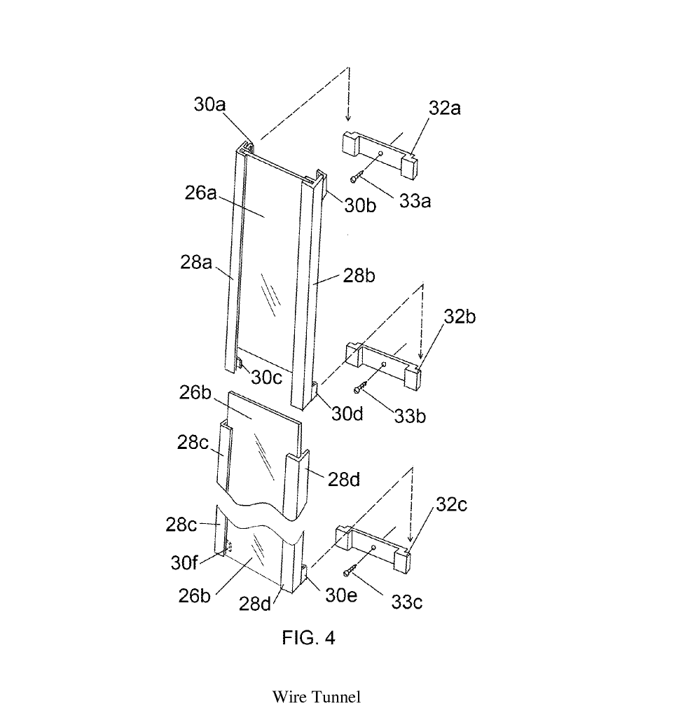

FIG. 4 comprises the wire tunnel consisting of a front panel assembly and panel brackets 32. The front panel assembly is comprised of a front panel 26a and 26b, side panels 28a, 28b, 28c and 28d tabs 30a, 30b, 30c, 30d, 30e and 30f. The front panel assembly engages the panel brackets 32a, 32b and 32c with the tabs 30. The front panel 26 is made of conventional thin wood paneling material or equivalent. The width of the front panel 26 is narrower than the opening behind the bottom shelf 20 of the video mantel FIG. 2 and wide enough to comfortably hide multiple wires laying flat to the wall behind it. The side panels 28 are made from vinyl F channel or equivalent material. The tabs 30 are fabricated from vinyl J channel or equivalent material and bonded to the side of the F channel. The panel brackets 32a, 32b and 32c are fabricated from suitable material such as wood or equivalent material. The panel brackets 32 are attached to the wall with sheet rock screws 33a, 33b and 33c.

### Operation FIGS. 1, 2, 3 and 4

The video mantel FIG. 2 is mounted to the wall in front of the exercise machine. The bottom of the video mantel is mounted high enough to clear any conflict with the front of the exercise machine. This allows the exercise machine to be placed as close to the wall as if the video mantel did not exist. With the height of the mantel identified, the mounting bracket 22 is installed to the wall. The video mantel is slid onto the mounting bracket 22 by engaging the bracket tangs 18. A video display 21 using it's built in stand is placed on the top shelf 2 of the video mantel. This automatically places the video display 21 at the right height for proper viewing.

The video display's 21 signal wiring and power lead is routed to their destination thru the hole 3 in the top shelf. The lower shelf 4 holds the electronic modules 35 for the desired video programming such as Video streamers, DVD players, cable or Satellite decoders, HDMI splitters etc. The electronic modules 35 are set back on shelf 4 obscuring views of all but the front panels of the electronic modules 35. The cut out 7 in the lower shelf provides easy access to route signal wires and power cords to the hidden chamber. The power leads for the various electronic modules 35 and video display 21 connect to the power strip 36 secured to the front wall 12 in the hidden chamber. All excess wiring to or between the various electronic modules 35 and display device 21 are bundled up and tied off in the hidden chamber.

All signal wires coming from remote locations (Ethernet, cable TV etc.) or going to remote locations (HDMI signals etc.) and the power cord 34 from the power strip 36 exit the bottom of the video mantel from the hidden chamber FIG. 2b. These wires run vertically down the wall. The wire tunnel FIG. 4 covers these wires and hides them from view keeping the appearance of the video mantel neat and clean. The wires are routed between the panel brackets 32 behind the wire tunnel front panel assembly. The panel brackets 32 are centered to the video mantel and mounted in a vertical line to the wall at spacing consistent with the tabs 30 on the wire tunnel front panel assembly. The front panel assembly is slid over the wires and attached to the panel brackets 32. At the bottom of the wire tunnel the wires exit and follow the baseboard to their remote destination. The power cord 34 exits the bottom of the wire tunnel and goes to the local power outlet 38. Any changes to electronic modules 35 or display device 21 or remote signals can easily be accomplished by removing the wire tunnel front panel assembly from the panel brackets 32, and remove the video mantel from its mounting bracket 22, make the changes required and reinstall same.

This design meets all the requirements for a stimulating video display while exercising:
Small footprint that takes up no floor space.
Eye level video display, the mantel mounts above the exercise equipment console setting the video display at the proper height.
Easy access, the mantel places all equipment within reach and directly in front of user.
Wall mounted, the video mantel and wire tunnel mount to brackets that make removal easy for future modification.
Esthetically pleasing, all electronic modules and wiring are concealed within the mantel. The mantel design appeals to all styles of architecture.
Clean power distribution, the hidden chamber hides the power distribution and excess wiring.

I claim:

1. A self contained video display comprising a wall mounted enclosure containing a plurality of shelves sufficient to contain the relevant electronic modules.

2. Self contained video display of claim 1 with a top shelf on said wall mounted enclosure sufficient for flat a panel video display to be placed using said video displays built in stand.

3. Self contained video display of claim 2 with said electronic modules installed on the lower shelves partially concealed from view.

4. Self contained video display of claim 3 with said wall mounted enclosure being sized to fit above the front console of the exercise equipment and maintain said video display at eye level while using the exercise equipment.

5. Self contained video display of claim 4 with a means concealed from view for power plugs from said electronic modules and said video display to be aggregated to a single power cord.

6. Self contained video display of claim 6 with a means concealed from view for interconnecting said electronic modules and said display.

7. Self contained video display of claim 6 with said wall mounted enclosure is reversibly mounted to the wall by bracket tangs that slide into grooves in a permanently attached mounting bracket.

8. A self contained video display of claim 7 given the appearance of a mantel piece over a fireplace.

9. Self contained video display of claim 8 with all signal wires and said power cord exit from the bottom of said wall mount enclosure and run vertically down and flat against the wall behind a wall panel cover.

10. Self contained video display of claim 9 with said signal wires and said power cord exiting said wall panel cover at the bottom edge of said wall panel cover.

11. Self contained video display of claim 10 with said wall panel cover reversibly attached to panel brackets by tabs that slide over said panel brackets.

12. Self contained video display of claim 11 with said panel brackets mounted to the wall.
